(19) United States
(12) Patent Application Publication
(10) Pub. No.: US 2023/0403574 A1
(43) Pub. Date: Dec. 14, 2023

(54) CENTRAL NODE AND A METHOD FOR REINFORCEMENT LEARNING IN A RADIO ACCESS NETWORK

(71) Applicant: Telefonaktiebolaget LM Ericsson (publ), Stockholm (SE)

(72) Inventors: Yu WANG, Solna (SE); Wenfeng HU, Täby (SE); Vidit SAXENA, Järfälla (SE); Pablo SOLDATI, Solna (SE)

(73) Assignee: Telefonaktiebolaget LM Ericsson (publ), Stockholm (SE)

(21) Appl. No.: 18/033,407

(22) PCT Filed: Oct. 28, 2020
(86) PCT No.: PCT/SE2020/051041

§ 371 Date: Apr. 24, 2023

(51) Int. Cl. H04W 24/02; G06N 3/092

(52) U.S. Cl. CPC H04W 24/02; G06N 3/092

(57) ABSTRACT

A method performed by a central node for controlling an exploration strategy associated to Reinforcement Learning, RL, in one or more RL modules in a distributed node in a Radio Access Network, RAN, is provided. The central node evaluates a cost of actions performed for explorations in the one or more RL modules, and a performance of the one or more RL modules. Based on the evaluation, the central node determines one or more exploration parameters associated to the exploration strategy. The central node controls the exploration strategy by configuring the one or more RL modules with the determined one or more exploration parameters to update its exploration strategy, enforcing the respective one or more RL modules to act according to the updated exploration strategy to produce data samples for the one or more RL modules in the distributed node.

### TECHNICAL FIELD

Embodiments herein relate to a central node and a method therein. In some aspects they relate to controlling an exploration strategy associated to Reinforcement Learning (RL) in one or more RL modules in a distributed node in a Radio Access Network (RAN).

Embodiments herein further relates to computer programs and carriers corresponding to the above method, and central node.

### BACKGROUND

In a typical wireless communication network, wireless devices, also known as wireless communication devices, mobile stations, stations (STA) and/or User Equipment (UE), communicate via a Local Area Network such as a Wi-Fi network or a Radio Access Network (RAN) to one or more core networks (CN). The RAN covers a geographical area which is divided into service areas or cell areas, which may also be referred to as a beam or a beam group, with each service area or cell area being served by a radio network node such as a radio access node e.g., a Wi-Fi access point or a radio base station (RBS), which in some networks may also be denoted, for example, a NodeB, eNodeB (eNB), or gNB as denoted in 5G. A service area or cell area is a geographical area where radio coverage is provided by the radio network node. The radio network node communicates over an air interface operating on radio frequencies with the wireless device within range of the radio network node.

Specifications for the Evolved Packet System (EPS), also called a Fourth Generation (4G) network, have been completed within the 3rd Generation Partnership Project (3GPP) and this work continues in the coming 3GPP releases, for example to specify a Fifth Generation (5G) network also referred to as 5G New Radio (NR) or Next Generation (NG). The EPS comprises the Evolved Universal Terrestrial Radio Access Network (E-UTRAN), also known as the Long Term Evolution (LTE) radio access network, and the Evolved Packet Core (EPC), also known as System Architecture Evolution (SAE) core network. E-UTRAN/LTE is a variant of a 3GPP radio access network wherein the radio network nodes are directly connected to the EPC core network rather than to RNCs used in 3G networks. In general, in E-UTRAN/LTE the functions of a 3G RNC are distributed between the radio network nodes, e.g. eNodeBs in LTE, and the core network. As such, the RAN of an EPS has an essentially “flat” architecture comprising radio network nodes connected directly to one or more core networks, i.e. they are not connected to RNCs. To compensate for that, the E-UTRAN specification defines a direct interface between the radio network nodes, this interface being denoted the X2 interface.

Multi-antenna techniques may significantly increase the data rates and reliability of a wireless communication system. The performance is in particular improved if both the transmitter and the receiver are equipped with multiple antennas, which results in a Multiple-Input Multiple-Output (MIMO) communication channel. Such systems and/or related techniques are commonly referred to as MIMO.

Deep Reinforcement Learning (RL)

A neural network is essentially a Machine Learning model, more precisely, Deep Learning, that is used in both supervised learning and unsupervised learning. A Neural Network is a web of interconnected entities known as nodes wherein each node is responsible for a simple computation.

RL is a powerful technique to efficiently learn a behavior of a system within a dynamic environment. By incorporating recent advances in deep artificial neural networks, deep RL (DRL) has been shown to enable significant autonomy in complex real-world tasks. DRL uses deep learning and reinforcement learning principles to create efficient algorithms applied on areas like robotics, video games, computer science, computer vision, education, transportation, finance, healthcare, etc. As a result, DRL approaches are quickly becoming state-of-the-art in robotics and control, online planning, and autonomous optimization.

Despite its significant success, the intuition behind DRL is relatively simple. For an observed environment state, a DRL agent attempts to learn the optimal action by exploring the space of available actions. For an observed state ‘S[t]’ at time ‘t’, the DRL agent selects an action ‘a[t]’ that is predicted to maximize the cumulative discounted rewards over the next several time intervals. The heuristically-configured discounting factor avoids actions that maximize the immediate, short-term, reward but lead to poor states in the future. After taking an action, the DRL agent feeds back the reward into a learning module, typically a neural network, which learns to make better action choices in subsequent time intervals.

At the beginning of its operation, DRL agent has incomplete, often zero, knowledge of the system. Depending on the tolerance of the system to occasional failures, the agent may either choose to collect data for offline learning through an existing policy, which is safer, or select actions online in some randomized manner, which is efficient. In either case, the collected data is used to iteratively update the model, for example the weight and bias variables within a neural network. The training parameters, such as the size of the neural network, number of iterative updates, and parameter update scheme are all configured heuristically based on empirical findings from state-of-the-art DRL implementations. As the DRL agent learns the true value of actions over time, the need for exploring random actions decreases as well. This decrease is encoded in an exploration rate variable whose value is slowly reduced to nearly zero with time.

Majority of radio network management and optimization problems are about tuning parameters to adapt to local propagation environment, traffic patterns, service types and UE device capabilities. DRL is a promising technique to automate such tuning. In the context of radio networks, DRL has recently been proposed for several challenging cellular network problems, ranging from data rate selection, beam management, to trajectory optimization for aerial base stations.

Machine Learning Architectures in Radio Networks

A radio network consists for multiple distributed base stations. The RL policy may be trained and/or inferred in a centralized, distributed or hybrid manner. FIG. 1a, b and c depict three RL architectures in a radio network such as a RAN where the RL model training and inference take place in different locations. FIG. 1a illustrates distributed learning, FIG. 1b illustrates centralized learning local inference, and FIG. 1c illustrates hybrid learning.

FIGS. 1a, b and c depict a global data pipeline 200, a Data pipeline for Local distributed node 1 referred to as 201a, a data pipeline for Local distributed node n referred to as 201n.

Further a Training for global node 210, a Training for local distributed node 1 referred to as 211a and a Training for local distributed node n referred to as 211n, an Inference for local distributed node 1 referred to as 221a, and an inference for local distributed node n referred to as 221n.

Yet further, a Global Training orchestrator, e.g. a learning orchestrator, referred to as 230, a Distributed node 1 referred to as 222a and a Distributed node n referred to as 222n.

Solid lines illustrate data movement of training data. Dotted lines illustrate model deployments, i.e. from trained models to inference using the trained models. Dashed lines illustrate the communication of model weights and training also referred to as learning, hyper parameters.

In the distributed learning architecture in FIG. 1a, both training and inference are located in the distributed nodes. One advantage of this architecture is the low inference latency especially for latency critical applications.

Since the memory and computation power of the distributed nodes are usually limited, the training can be moved to a central node as shown in the centralized learning local inference architecture in FIG. 1b. Another advantage of this solution is the higher amount of training data collected from the multiple distributed nodes.

The hybrid learning architecture in FIG. 1c provides different dynamics between the central and distributed nodes. In this scheme, a central learning orchestrator controls or instructs the training and inference in the distributed nodes.

E-UTRAN and NG-RAN Architecture Options

The current 5G RAN (NG-RAN) architecture is depicted and described in 3GPP TS 38.401v15.4.0 as follows. Mapped to the RL architecture, centralized learning functions may be located in either Fifth Generation Core network (5GC) or gNB-Central Unit (CU), and gNB-Distributed Unit (DU) is an example of the distribute node.

FIG. 2 depicts an overall architecture of NG architecture. The NG architecture may be further described as follows. The NG-RAN comprises a set of gNBs connected to the 5GC through the NG. A gNB can support FDD mode, TDD mode or dual mode operation. gNBs can be interconnected through the Xn interface. A gNB may comprise a gNB-CU and one or more gNB-DUs. A gNB-CU and a gNB-DU are connected via F1 logical interface. One gNB-DU is connected to only one gNB-CU. For resiliency, a gNB-DU may be connected to multiple gNB-CU by appropriate implementation. NG, Xn and F1 are logical interfaces. The NG-RAN is layered into a Radio Network Layer (RNL) and a Transport Network Layer (TNL). The NG-RAN architecture, i.e., the NG-RAN logical nodes and interfaces between them, is defined as part of the RNL. For each NG-RAN interface, NG, Xn, and F1, the related TNL protocol and the functionality are specified. The TNL provides services for User Plane (UP) transport and signalling transport.

A gNB may also be connected to an LTE eNB via the X2 interface. In this architectural option an LTE eNB connected to the Evolved Packet Core network is connected over the X2 interface with a so called nr-gNB. The latter is a gNB not connected directly to a CN and connected via X2 to an eNB for the sole purpose of performing dual connectivity.

In yet another architecture option a gNB may be connected to an eNB via an Xn interface. In this option both gNB and eNB are connected to the 5GC and can communicate over the Xn interface.

It is worth noticing that RAN nodes can not only communicate via direct interfaces such as the X2 and Xn but also via CN interfaces such as the NG and S1 interfaces. Such communication requires the involvement of CN nodes and/or transport nodes (such as IP packet routers, Ethernet switches, microwave links or optical ROADMs) to route and forward messages from the source RAN node to the target RAN node.

The architecture in FIG. 2 can be expanded by spitting the gNB-CU into two entities. One gNB-CU-UP, which serves the user plane and hosts the Packet Data Convergence Protocol (PDCP) protocol, and one gNB-CU-Control Plane (CP), which serves the control plane and hosts the PDCP and Radio Resource Control (RRC) protocol. For completeness it should be mentioned that a gNB-DU hosts the Radio Link Control (RLC) protocol, the Medium Access Control (MAC) protocol and the Physical Layer (PHY) protocol.

RL Exploration and Exploitation in Radio Networks

One challenge about the RL technique, comparing with rule-based methods, is the risk of significant performance degradation in the radio network when taking random actions. For example, performance degradation in the form of coverage holes might be a result of an action of reducing cell transmission power. Such risks are rooted in the way a RL agent explores the environment.

The balance between exploration and exploitation is a key aspect of RL when deciding which action to take. While exploitation is about taking advantage of the learning in the past, exploration is a procedure to learn new knowledge, e.g. by taking random actions and observing the consequences. Usually, a RL agent applies a high exploration rate in the beginning phase of learning when the policy has only been trained with limited amount of data samples. As the training continues and the trained policy becomes more reliable, the exploration rate is gradually reduced to a value close to zero.

One way to reduce the risk of taking random actions during exploration is to craft the action space so that all actions are more or less safe to the system. To craft used herein means to define a set of allowed actions for an individual or a group of states. At least, no catastrophic consequences should occur by taking any action. In one prior-art method, a heuristic model is deployed in parallel to a RL policy. When the performance of the RL policy degrades below a threshold, the heuristic model is activated to replace the RL policy.

Learning an RL strategy, also referred to as a policy or a model, that performs well requires proper exploration to produce rich training data samples. During explorations, an RL agent may follow a randomization exploration strategy to explore combination of state and actions that would otherwise be unknown. While this allows to possibly learn better state-action combinations from which the agent policy can be improved upon, taking an action at random in a given state of the system may also lead to suboptimal behavior and therefore a performance degradation of the user experience and/or system availability, accessibility, reliability and retainability.

### SUMMARY

As a part of developing embodiments herein a problem was identified by the inventors and will first be discussed.

As such, while it is necessary to explore actions at random to learn unseen parts of the state-action space, the resulting RAN system performance, e.g. availability, accessibility, reliability and retainability, and user experience may be negatively affected by the exploration. It is therefore necessary to control and optimize the collection of data samples via proper exploration strategies, so as to minimize the system performance degradation due to exploration.

In addition to the exploration rate, efficient operation of DRL requires careful tuning of training parameters, including but not limited to, the discount factor, the number of parameter update iterations, the parameter update scheme, etc. A discount factor when used herein means the weight of future rewards respect to the immediate reward. It is computationally very expensive to obtain the optimal training parameters. The agent typically tries out different parameter configurations and selects those that best improve the learning performance. Hence, techniques that efficiently select the optimal training parameters lead to improvements in the overall system performance.

An object of embodiments herein is to provide an improved performance of a RAN using RL with low risk of instantaneous performance degradation due to the exploration.

According to an aspect, the object is achieved by a method performed by a central node for controlling an exploration strategy associated to RL in one or more RL modules in a distributed node in a RAN. The central node evaluates a cost of actions performed for explorations in the one or more RL modules, and a performance of the one or more RL modules. Based on the evaluation, the central node determines one or more exploration parameters associated to the exploration strategy. The central node controls the exploration strategy by configuring the one or more RL modules with the determined one or more exploration parameters to update its exploration strategy. This enforces the respective one or more RL modules to act according to the updated exploration strategy to produce data samples for the one or more RL modules in the distributed node.

According to another aspect, the object is achieved by a central node configured to control an exploration strategy associated to RL in one or more RL modules in a distributed node in a RAN. The central node is further configured to:
Evaluate a cost of actions performed for explorations in the one or more RL modules, and a performance of the one or more RL modules,
based on the evaluation, determine one or more exploration parameters associated to the exploration strategy, and
control the exploration strategy by configuring the one or more RL modules with the determined one or more exploration parameters to update its exploration strategy, to enforce the respective one or more RL modules to act according to the updated exploration strategy to produce data samples for the one or more RL modules in the distributed node.

Thanks to that the evaluated a cost of actions performed for explorations in the one or more RL modules, and a performance of the one or more RL modules e.g. identifies services of high importance or strict requirements according to the evaluation, the central node may determine the one or more exploration parameters associated to the exploration strategy to achieve a reduced exploration in the presence of the identified services of high importance or strict requirements according to the evaluation. This results in a reduced impact of performance degradation of the RAN is achieved by a reduced exploration in the presence of services of high importance or strict requirements according to the evaluation. This in turn provides an improved performance of the RAN and improved level of user satisfaction using RL.

### BRIEF DESCRIPTION OF THE DRAWINGS

FIGS. 1 a, b, and c are schematic block diagrams illustrating prior art.

FIG. 2 is a schematic block diagram illustrating prior art.

FIGS. 3 a and b are schematic block diagrams depicting embodiments of a wireless communication network.

FIG. 4 is a flowchart depicting embodiments of a method in a central node.

FIGS. 5 a and b are schematic block diagrams depicting embodiments in a central node.

FIG. 6 schematically illustrates a telecommunication network connected via an intermediate network to a host computer.

FIG. 7 is a generalized block diagram of a host computer communicating via a base station with a user equipment over a partially wireless connection.

FIGS. 8 to 11 are flowcharts illustrating methods implemented in a communication system including a host computer, a base station and a user equipment.

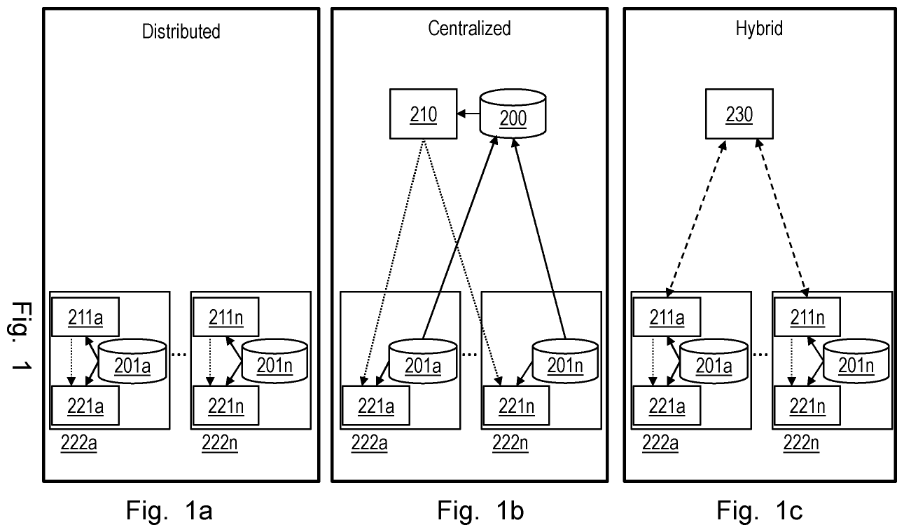

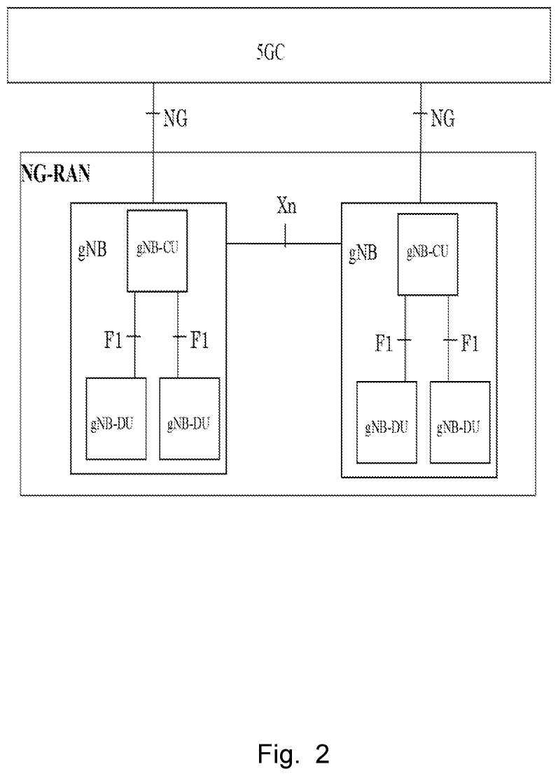

### DETAILED DESCRIPTION

An example of embodiments herein relates to methods for controlling exploration and training strategies associated to RL in a wireless communications network.

Embodiments herein are e.g. related to Radio network optimization, Network Management, Reinforcement Learning, and/or Machine Learning.

In some examples of embodiments herein it is provided a signaling method between a central node and a distributed node to exchange control messages to properly configure exploration and training parameters of an RL algorithm in the distributed node.

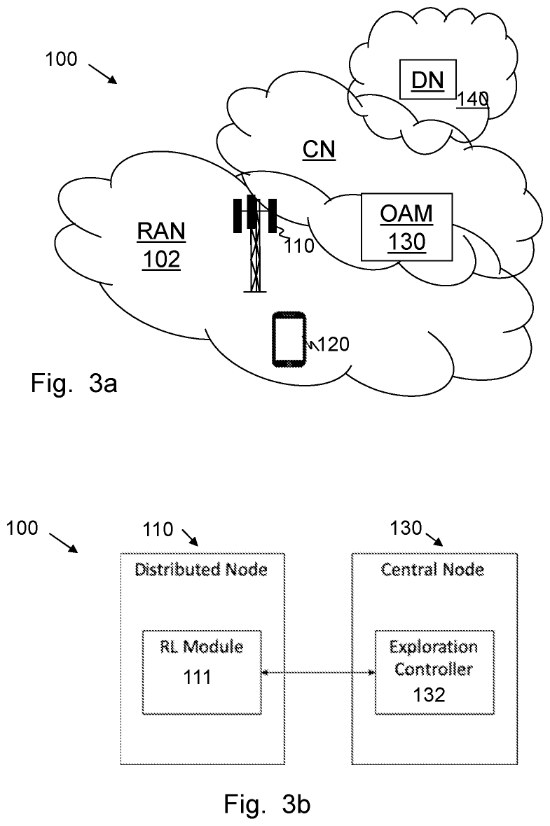

FIG. 3a is a schematic overview depicting a wireless communications network 100. FIG. 3b illustrates a network architecture with one distributed node 110 and one central node 130 in the wireless communications network 100. wherein embodiments herein may be implemented. The wireless communications network 100 comprises one or more RANs, such as the RAN 102 and one or more CNs. The wireless communications network 100 may use 5 Fifth Generation New Radio, (5G NR) but may further use a number of other different Radio Access Technologies (RAT)s, such as, (LTE), LTE-Advanced, Wideband Code Division Multiple Access (WCDMA), Global System for Mobile communications/enhanced Data rate for GSM Evolution (GSM/EDGE), Worldwide Interoperability for Microwave Access (WiMax), or Ultra Mobile Broadband (UM B), just to mention a few possible implementations.

Network nodes, such as a distributed node 110, operate in the RAN 102. The distributed node 110 may provide radio access in one or more cells in the RAN 102. This may mean that the distributed node 110 provides radio coverage over a geographical area by means of its antenna beams. The distributed node 110 may be a transmission and reception point e.g. a radio access network node such as a base station, e.g. a radio base station such as a NodeB, an evolved Node B (eNB, eNode B), an NR Node B (gNB), a base transceiver station, a radio remote unit, an Access Point Base Station, a base station router, a transmission arrangement of a radio base station, a stand-alone access point, a Wireless Local Area Network (WLAN) access point, an Access Point Station (AP STA), an access controller, a UE acting as an access point or a peer in a Device to Device (D2D) communication, or any other network unit capable of communicating with a radio device within the cell served by network node 110 depending e.g. on the radio access technology and terminology used.

The distributed node 110 comprises one or more one or more RL modules 111. The distributed node 110 is adapted to execute RL in the one or more RL modules 111.

UEs such as the UE 120 operate in the wireless communications network 100. The UE 120 may e.g. be an NR device, a mobile station, a wireless terminal, an NB-IoT device, an eMTC device, a CAT-M device, a WiFi device, an LTE device and an a non-access point (non-AP) STA, a STA, that communicates via such as e.g. the distributed node 110, one or more RANs such as the RAN 102 to one or more CNs. It should be understood by the skilled in the art that the UE 120 relates to a non-limiting term which means any UE, terminal, wireless communication terminal, user equipment, (D2D) terminal, or node e.g. smart phone, laptop, mobile phone, sensor, relay, mobile tablets or even a small base station communicating within a cell.

Core network nodes, such as e.g. a central node 130, operate in the CN. The central node 130 is adapted to control exploration strategies associated to RL in the one or more RL modules 111 in the distributed node 110, e.g. by means of an exploration controller 132 in the central node 130.

Methods herein may e.g. be performed by the central node 110. As an alternative, a Distributed Node (DN) and functionality, e.g. comprised in a cloud 140 as shown in FIG. 3a, may be used for performing or partly performing the methods.

FIG. 3b Figure illustrates a hybrid RL architecture in the RAN 102 network architecture with one distributed node 110 and one central node 130, wherein embodiments herein may be implemented.

In some example embodiments, the distributed node 110 is an eNB and/or gNB and the central node 130 may be an Operation and Maintenance (OAM) node. One or more RL modules 111 are located in the distributed node 110. The respective one or more RL module 111 is a module that trains a policy and uses the policy to infer an action, e.g. changing the values of one or multiple configuration parameters in the distributed node 110. An exploration controller 132 may be located in the central node 130. The exploration controller 132 is a unit that may decide the value of one or multiple exploration parameters for the RL modules 111.

The central node 130 has access to knowledge related to the cost of random actions taken by the RL modules 111 for exploration and the performance of the RL modules 111 in distributed nodes such as the distributed node 130.

Based on this knowledge, the central node 130 may
determine one or more parameters associated to a training strategy for one or more RL modules 111 of the distributed node 110, and
configure the one or more RL modules 111 by transmitting to the distributed node 110, a control message comprising the determined one or more parameters associated to an exploration strategy for the one or more RL modules 111 of the distributed node 110.

Based on this knowledge, the central node 130 may further
determines one or more parameters associated to an exploration strategy for the one or more RL modules 111 of a distributed node 110, and
configure the one or more RL modules 111 by transmitting to the distributed node 110, a control message comprising the determined one of more training parameters for the one or more RL modules 111 of the distributed node 110.

Exploration

The wordings exploration and exploration strategy when used herein e.g. means the behaviour of the one or more RL modules 111 to probe state transition and resulted reward in an environment by randomly selecting an action.

The one or more exploration parameters to be determined herein will e.g. be used for the one or more RL modules 111 to decide the frequency of selecting a random action and/or the candidate actions that can be randomly selected in a given state.

Training

Compared to exploration and exploration strategy, the wordings training and training strategy when used herein e.g. means the process to update a policy based on the observed state transition and resulted reward after taking an action.

The one or more training parameters to be determined may e.g. be used for the RL module to control the training process by specifying the configuration of methods for ML model update.

The types of and the formats of the parameters associated to an exploration strategy that may be signaled with the control message explained more in detailed below.

Upon the reception of the message, the distributed node 110 applies the exploration and the training parameters configured by the central node 130 to the corresponding exploration strategy and training strategy for one or more RL modules 111.

Embodiments herein may provide following advantages:

Example embodiments of the provided method controls the exploration strategy and possibly the training strategy in the distributed node 110, e.g. by the exploration controller 132 located in the central node 130 where a richer knowledge is available e.g. compared to the distributed node 110. The richer knowledge may comprise, in the serving area of the distributed node 110, whether there are prioritized users, whether the served traffic is critical, whether there is an important event, etc.

This results in:
A reduced impact of performance degradation of the RAN and user experiences by a reduced exploration in the presence of services of high importance or strict requirements. This is since unpredictable outcomes of random actions are avoided.
An improved RL policy performance by an increased exploration when the performance of a RL policy in the distributed node degrades below a certain level.
An improved learning performance of RL by configuring efficient training parameters for the one or more RL modules 111 in the distributed node 130.

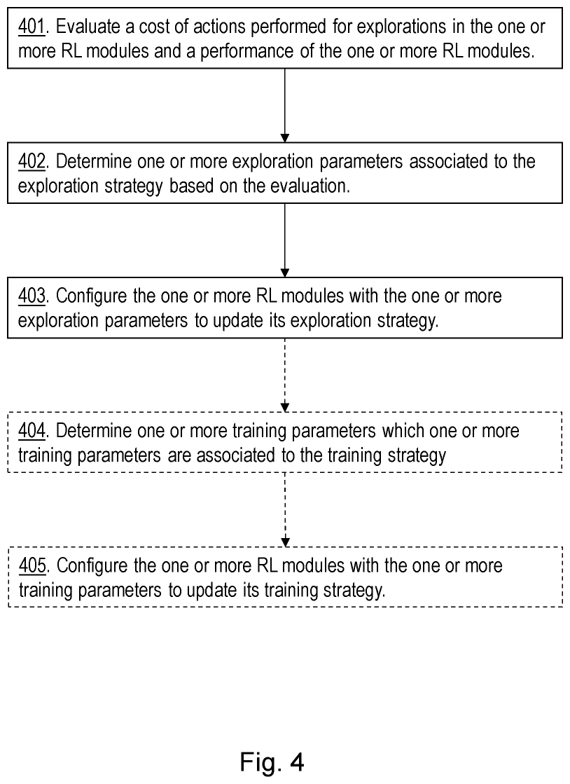

FIG. 4 shows example embodiments of a method performed by the central node 130 for controlling an exploration strategy associated to RL in the one or more RL modules 111 in the distributed node 110 in the RAN 102.

The method comprises one or more of the following actions, which actions may be taken in any suitable order. Actions that are optional are marked with dashed boxes in the figure.

Action 401

The central node 130 evaluates a cost of actions performed for explorations in the one or more RL modules 111 and a performance of the one or more RL modules 111.

The cost of actions performed for explorations e.g. means degraded user experience with lower throughput and/or higher latency and degraded system performance with worse availability, accessibility, reliability and/or retainability. The cost of actions performed for explorations may e.g. be evaluated by predicting the outcome of the actions based on knowledge obtained from domain experts and/or past experiences.

The performance of the one or more RL modules 111 means the capability to achieve high rewards which is related to user experiences and system performance. The performance of the one or more RL modules 111 may e.g. be evaluated by the value of reward signals and/or Key Performance Indicators (KPIs) indicating user experience and system performance.

Action 402

Based on the evaluation, the central node 130 determines one or more exploration parameters associated to the exploration strategy.

These one or more exploration parameters may later be used by the distributed node 110 for an exploration procedure according to the exploration strategy. i.e. the procedure to learn new knowledge, e.g. by taking random actions according to the determined one or more exploration parameters and observing the consequences.

In some embodiments the one or more exploration parameters is determined for a specific cell or group of cells controlled by the distributed node 110.

The one or more exploration parameters may be determined further based on any one or more out of: Which may mean that the cost of actions performed for explorations in the one or more RL modules 111 and the performance of the one or more RL modules 111 may comprise any one or more out of:
a performance of the RAN 102,
service requirements associated to services and applications provided by the distributed node 110, and
importance of services provided by the distributed node 110.

The one or more exploration parameters may comprise any one or more out of:
an index indicating a type of the exploration strategy, and
a value of the respective one or more exploration parameters.

Action 403

The central node 130 controls the exploration strategy by configuring the one or more RL modules 111 with the determined one or more exploration parameters to update its exploration strategy. To update its exploration strategy e.g. means to change the frequency of selecting a random action and/or changing the candidate actions that may be randomly selected in a given state.

This enforces the respective one or more RL modules 111 to act according to the updated exploration strategy to produce data samples for the one or more RL modules 111 in the distributed node 110. To act according to the updated exploration strategy to produce data samples means to select an action according to the updated exploration strategy and observe system transition and resulted reward.

It is an advantage that the central node 130 controls the exploration strategy since the central node 130 may possess more knowledge than the distributed node 110 to evaluate the cost of the exploration in the distributed node 110.

In some embodiments the central node 130 configures the one or more RL modules 111 with the determined one or more exploration parameters by sending the one or more exploration parameters in a first control message.

In some embodiments the method is further performed for controlling a training strategy associated to the RL in the one or more RL modules 111 in the distributed node 110. In these embodiments, the below actions 404-405 are performed.

Action 404

In these embodiments the central node 130 determines one or more training parameters based on the evaluation. The one or more training parameters are associated to the training strategy.

The one or more training parameters may be determined further based on any one or more out of: Which may mean that the cost of actions performed for explorations in the one or more RL modules 111 and the performance of the one or more RL modules 111 may in these embodiments comprise any one or more out of:
Importance of services provided by the distributed node 110,
requirements of services provided by the distributed node 110,
a search policy at the central node 130, and
observed performance of the distributed node 110 for a variety of KPIs.

The one or more training parameters may comprise any one or more out of:
A discount factor for calculating the value of an action,
a type of gradient and the corresponding one or more training parameters, and
an index indicating a type of learning scheme.

Action 405

In these embodiments the central node 130 further configures the one or more RL modules 111 with the determined one or more training parameters to update its training strategy. It is an advantage that the central node 130 controls the training strategy since the central node 130 may possess more knowledge than the distributed node 110 about the best strategy for training.

This enforces the respective one or more RL modules 111 in the distributed node 110 to act according to the updated training strategy to use the produced data samples to update an RL policy of the RL module. To act according to the updated training strategy to use the produced data samples to update an RL policy of the RL module means to apply the method and hyperparameters specified in the updated training strategy to update the RL policy of the RL module.

In some embodiments the central node 130 configures the one or more RL modules 111 with the one or more training parameters, by sending the one or more training parameters in a second control message.

The embodiments described above will now be further explained and exemplified. The example embodiments described below may be combined with any suitable embodiment above.

Method in the Central Node 130 and its Embodiments.

Example embodiments herein discloses methods performed in the central node 130 for optimizing and controlling the configuration of the exploration strategy and possibly also the training strategy associated to RL, also referred to as machine learning, algorithms executed by the distributed node 130. In one embodiment, the distributed node 110 is an eNB or gNB, and the central node 130 is an OAM node.

Exploration

As mentioned above the method may e.g. comprise the following related to the Actions described above:
Determining 402 one or more parameters associated to the exploration strategy for one or more RL modules 111 of the distributed node 110;
Transmitting 403 a control message to the distributed node 110 comprising the one or more parameters associated to an exploration strategy for one or more RL modules 111 of the distributed node 110.

In some embodiments, the central node 130 determines the one or more parameters associated to the exploration strategy for the one or more RL modules 111 of the distributed node 110 for a specific cell or group of cells controlled by the distributed node 110.

In some other embodiments of the method, the central node 130 determines the one or more parameters associated to the exploration strategy for the one or more RL modules 111 of a distributed node 110 based on network performance and/or service requirements associated to services and applications provided by the distributed node 110. Such examples may comprise:
The importance and criticality of services provided by the distributed node 110. The wordings importance and criticality when used herein means the level of impact to user satisfaction and/or the level of impact to the system availability, accessibility, reliability and retainability KPI. The distributed node 110 may provide services of different importance and criticality such as e.g. critical IoT services, services for a critical event, etc.
Existence of VIP users in the coverage area of one or more radio cells controlled by the distributed node 110; VIP users means users of high business values, e.g. golden subscription users.
Requirements of services provided in of one or more radio cells controlled by the distributed node 110, for instance in terms of required data rate, latency, reliability, energy efficiency, etc. Such requirements may be expressed in terms of minimum requirement, maximum requirement, average required, statistical deviation from a reference requirement or a combination thereof.
   In one example, such requirements are defined as requirements associated to one or more network slices supported in the coverage area of one or more radio cell of the distributed node 110.
   In another example, the requirements are derived based on the type of services provided by the distributed node 110. The service type, e.g. web browsing, file sharing or YouTube video, may be identified by deep package inspection.

For instance, in case the central node 130 detects critical or prioritized services, or VIP users, or services with stringent requirements in terms of data rate, latency, reliability, energy efficiency, etc. to be provided within the coverage area of one or more radio cells controlled by a distributed node 110 where exploration is configured, the central node 130 may determine to reduce the amount of exploration by changing the one or more parameters of the exploration strategy.

For example, with an E-greedy exploration strategy, wherein a control policy is tasked to explore with probability ∈∈[0, 1], i.e., acting according to a random probability distribution, such as taking an action with uniform probability among all available actions, and to act according to the control policy with probability 1−∈, the central node 130 may determine to reduce the current value E configured for the distributed node 110 so as to reduce the average number of actions taken according to a random probability distribution. Vice versa, when the central node 130 detects that there are no critical traffic or services to be supported in any of the cells controlled by the distributed node 110, the central node 130 may determine to increase the explorative behavior of the distributed node 110.

In some embodiments of the method, the central node 130 determines the one or more parameters associated to the exploration strategy for the one or more RL modules 111 of the distributed node 110 based on network performance experienced in the coverage area of the radio cells controlled by the distributed node 110. For instance, if the network performance measured in the radio cells controlled by the distributed node 110 falls below a threshold or is lower compared to the performance of other radio cells controlled by other distributed nodes, for instance with similar deployment and radio conditions, the central node 130 may infer that the RL policy used by the distributed node 110 in one or more controlled radio cells is not sufficiently good, and may thereby determine to increase the explorative behavior of the distributed node 110 in one or more of its controlled cells in order to collect new data that could improve the current policy.

In some embodiments the central node 130 may determine to change exploration strategy for the distributed node 110. Examples of possible exploration strategies include, but are not limited to:
Random exploration according to a given probability distribution over the action space [symbol] , such as uniform distribution, e.g., such as ∈-greedy exploration strategy, or a non-uniform distribution, such as a semi-uniform distributed exploration, etc.
Boltzmann-Distributed Exploration, which considers the estimated utility of all actions a∈ [symbol] according to the probability distribution

$${P}_{a} = {e}^{f ( a ) {θ}^{- 1}} / {\sum }_{i ∖ in 𝒜} {e}^{f ( i ) {θ}^{- 1}}$$

wherein Pₐ is the probability of taking an action a, i\in [symbol] means action i in an action set A, a is the action whose taken probability is under calculation and i is an action in the action set A and
where the amount of randomness is controlled by the parameter θ∈[0, ∞), with θ→0 indicating pure random behavior, and
Counter-Based Exploration which uses the difference between the counter value for the current state c(s) and the expected counter value for the state that results from taking an action E[c|s, a]
Counter/Error-Based Exploration

Recency-Based Exploration

Therefore, the central node 130 may signal to the distributed node 110 which exploration strategy to use and the corresponding the one or more parameters. For instance, the central node 130 may signal an exploration strategy as one element of an enumerated list or using a bitmap with each bit indicating one specific exploration strategy and setting the bit to equal to 1 only for the selected exploration strategy.

In case the distributed node 110 is using an exploration strategy where the one or more parameters are changed dynamically and locally by the distributed node 110, the central node 130 may further:
Transmit a signal to the distributed node 110 requesting the current one or more parameters used for the exploration procedure.
Receive a response from the distributed node 110 comprising the one or more parameters currently used for exploration.
Then determining one or more updated parameter associated to the exploration strategy for the one or more RL modules 111 of the distributed node 110 based on the response message.

For instance, if the distribute node 110 is configured to explore according to an E-greedy exploration strategy with decaying and/or annihilating exploration over time, the value of the exploration parameter E initially configured by the central node 130 for the distributed node 110 may be reduced by the distributed node 110 over time so as to reduce the amount of exploration. If the central node 130 has not configured the distributed node 110 with a specific decaying and/or annihilating exploration parameters, the central node 130 may not be aware of the current value of the parameter E governing the amount of exploration at the distributed node 110. The knowledge of such parameter would be necessary to the central node 130 to determine whether the exploration strategy used by the distributed node 110, or its associated one or more parameters, need to be updated, e.g., due to critical or prioritized services or users according to other embodiments.

Training

As mentioned above the method may in some embodiments further comprise the following, related to the Actions described above:
Determining 404 one or more parameters associated to the training strategy for the one or more RL modules 111 of a distributed node 110;
Transmitting 405 a control message to the distributed node 110 comprising one of more training parameters for one or more RL modules 111 of the distributed node 110.

In some embodiments, the central node 130 determines one or more training parameters such as one or more efficient training parameters. For example, the central node 130 may signal different learning parameters to each of different distributed nodes such as e.g. the distributed node 110. For a distributed node, e.g. the distributed node 110, that handles critical or prioritized traffic, the central node 130 may configure training parameters that have provided a high training performance, also referred to as learning performance, in previous instances. Learning performance when used herein may mean the achieved accuracy of the model prediction after trained with a given number of samples. For other distributed nodes, which in some embodiments also may be the distributed node 110, the central node 130 may configure training parameters for which the impact on learning performance is insufficiently known. In this manner, the central node 130 may efficiently obtain knowledge about the best training parameter configurations comprising the one or more training parameters, while minimizing the adverse impact on the overall system performance. Periodically, the central node 130 may update the training parameters for all or a subset of the distributed nodes, e.g. comprising the distributed node 110, in response to the type of traffic being currently served by that distributed node, and the knowledge about the training parameters collected so far. The central node 130 may choose training parameters based on, for example,
Random selection from a grid of feasible training parameters such as the one or more training parameters.
Linear interpolation between the one or more training parameters that provide the best performance across multiple distributed node 110s.
Linear interpolation between the one or more training parameters where the weighting is done based on the number of training samples, the type of network traffic served by the distributed node 110, or any combination of related metrics.
Bayesian optimization, where the observed performance for the distributed node 110 is probabilistically modeled, and this model is sampled to get the next set of training parameters.
Population-based training, where the observed performance across the distributed nodes, e.g. comprising the distributed node 110, is used to estimate a next set of one or more training parameters to be applied.

At the distributed node 110 the following actions may be performed.
Receiving, from the central node 130, a control message comprising one or more exploration parameters associated to an exploration strategy for the one or more RL modules 111 of the distributed node 110.
Appling the exploration parameters configured by the central node 130 to the corresponding exploration strategy for the one or more RL modules 111.
Responding, to a request from the central node 130, with a message comprising the current parameters used for exploration,
Receiving, form the central node 130, a control message comprising one or more parameters associated to a training strategy for the one or more RL modules 111 of the distributed node 110.
Applying the learning parameters configured by the central node 130 to the corresponding training strategy for the one or more RL modules 111.
Transmitting to the central node 130, a message comprising the current training parameters and the KPIs related to the performance of the learning scheme, from the distributed node 110.

Example of embodiments herein provide:
A signaling method between a central node such as the central node 130 and a distributed node such as the distributed node 110 to communicate one or more exploration parameters associated to an exploration strategy for the one or more RL modules 111s of a distributed node 110.
   The one or more exploration parameters are determined by the central node 130 e.g. based on:
      The importance of the services provided by the distributed node 110
      The requirements of the services provided by the distributed node 110
      The performance of the RL policies located in the distributed node 110.
   The one or more exploration parameters associated to the exploration strategy may include:
      An index indicating a type of the exploration strategy
      A value of a parameter associated to the exploration strategy, e.g. E in ∈-greedy exploration and θ in Boltzmann-distributed exploration
A signaling method between a central node such as the central node 130 and a distributed node such as the distributed node 110 to communicate one or more training parameters associated with a training strategy for the one or more RL modules 111 of the distributed node 110.
   The parameters are determined by the central node 130 e.g. based on:
      The importance of the services provided by the distributed node 110.
      The requirements of the services provided by the distributed node 110.
      The search policy at the central node 130, for example, grid search, interpolation, Bayesian approaches, or population-based training.
      The observed performance of the distributed node 110 for a variety of KPIs.
   The parameters associated with the training strategy e.g. include:
      A discount factor for calculating the value of an action.
      The type of gradient, such as e.g. full batch, mini batch, . . . , and the associated one or more training parameters such as e.g. number of epochs, number of samples per epoch, . . . .
      An index indicating the type of learning scheme, e.g., stochastic gradient descent, Adam, etc.

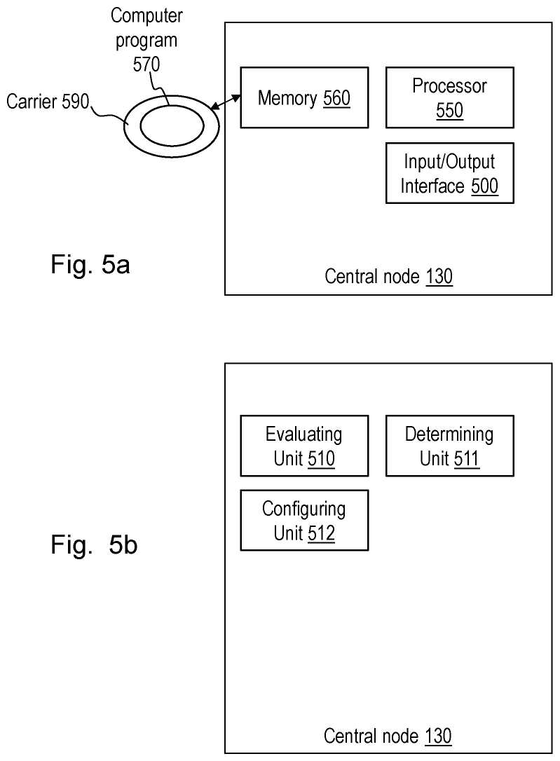

To perform the action as mentioned above, the central node 130 may comprise the arrangement as shown in FIGS. 5 a and b. The central node 130 is configured to control an exploration strategy associated to RL in the one or more RL modules 111 in the distributed node 110 in the RAN 102. The central node 130 may in some embodiments be configured to control a training strategy associated to the RL in the one or more RL modules 111 in the distributed node 110.

The central node 130 may comprise a respective input and output interface 500 configured to communicate with e.g. the distributed node 110, see FIG. 5a. The input and output interface 500 may comprise a wireless receiver (not shown) and a wireless transmitter (not shown).

The central node 130 may further be configured to, e.g. by means of an evaluating unit 510 in the central node 130, evaluate a cost of actions performed for explorations in the one or more RL modules 111, and a performance of the one or more RL modules 111.

The central node 130 may further be configured to, e.g. by means of a determining unit 511 in the central node 130, based on the evaluation, determine one or more exploration parameters associated to the exploration strategy.

The one or more exploration parameters may be adapted to be determined, e.g. by means of the determining unit 511, for a specific cell or group of cells controlled by the distributed node 110.

The central node 130 may further be configured to, e.g. by means of the determining unit 511, determine the one or more exploration parameters based on any one or more out of:
a performance of the RAN 102 and
service requirements associated to services and applications arranged to be provided by the distributed node 110,
importance of services arranged to be provided by the distributed node 110.

The one or more exploration parameters may be adapted to comprise any one or more out of:
an index adapted to indicate a type of the exploration strategy, and
a value of the respective one or more exploration parameters.

The central node 130 may further be configured to, e.g. by means of the determining unit 511, determine one or more training parameters, which one or more training parameters are adapted to be associated to the training strategy.

The central node 130 may further be configured to, e.g. by means of the determining unit 511, determine the one or more training parameters based on any one or more out of:
importance of services arranged to be provided by the distributed node 110,
requirements of services arranged to be provided by the distributed node 110,
a search policy at the central node 130,
observed performance of the distributed node 110 arranged for a variety of KPIs.

The one or more training parameters may be adapted to comprise any one or more out of:
a discount factor arranged for calculating the value of an action,
a type of gradient and the corresponding one or more training parameters, and
an index adapted to indicate a type of learning scheme.

The central node 130 may further be configured to, e.g. by means of an configuring unit 512 in the central node 130, control the exploration strategy by configuring the one or more RL modules 111 with the determined one or more exploration parameters to update its exploration strategy, to enforce the respective one or more RL modules 111 to act according to the updated exploration strategy to produce data samples for the one or more RL modules 111 in the distributed node 110.

The central node 130 may further be configured to, e.g. by means of the configuring unit 512, configure the one or more RL modules 111 with the determined one or more training parameters to update its training strategy, to enforce the respective one or more RL modules 111 in the distributed node 110 to act according to the updated training strategy to use the produced data samples to update an RL policy of the RL module.

The central node 130 may further be configured to, e.g. by means of the configuring unit 512, any one or more out of:
configure one or more RL modules 111 with the determined one or more exploration parameters arranged to be performed by sending the one or more exploration parameters in a first control message, and
configure one or more RL modules 111 with the one or more training parameters, arranged to be performed by sending the one or more training parameters in a second control message.

The embodiments herein may be implemented through a processor or one or more processors, such as a processor 550 of a processing circuitry in the central node 130 in FIG. 5a, together with computer program code for performing the functions and actions of the embodiments herein. The program code mentioned above may also be provided as a computer program product, for instance in the form of a data carrier carrying computer program code for performing the embodiments herein when being loaded into the central node 130. One such carrier may be in the form of a CD ROM disc. It is however feasible with other data carriers such as a memory stick. The computer program code may furthermore be provided as pure program code on a server and downloaded to the central node 130.

The central node 130 may further comprise a memory 560 comprising one or more memory units. The memory 560 comprises instructions executable by the processor 550 in the central node 130. The memory 560 is arranged to be used to store, e.g. training parameters, exploration parameters, training strategy, control messages, data samples, RL policies, information, data, configurations, and applications, to perform the methods herein when being executed in the central node 130.

In some embodiments, a computer program 570 comprises instructions, which when executed by the at least one processor 550, cause the at least one processor 550 of the central node 130 to perform the actions above.

In some embodiments, a carrier 580 comprises the computer program 570, wherein the carrier 580 is one of an electronic signal, an optical signal, an electromagnetic signal, a magnetic signal, an electric signal, a radio signal, a microwave signal, or a computer-readable storage medium.

Those skilled in the art will also appreciate that the units in the units described above may refer to a combination of analog and digital circuits, and/or one or more processors configured with software and/or firmware, e.g. stored in the central node 130 that when executed by the one or more processors such as the processors or processor circuitry described above. One or more of these processors, as well as the other digital hardware, may be included in a single Application-Specific Integrated Circuitry (ASIC), or several processors and various digital hardware may be distributed among several separate components, whether individually packaged or assembled into a system-on-a-chip (SoC).

Abbreviations

| Abbreviation | Explanation |
|---|---|
| RAN | Radio Access Network |
| RL | Reinforcement Learning |
| DRL | Deep Reinforcement Learning |
| OAM | Operation and Maintenance |
| eNB | eNodeB |

Further Extensions and Variations

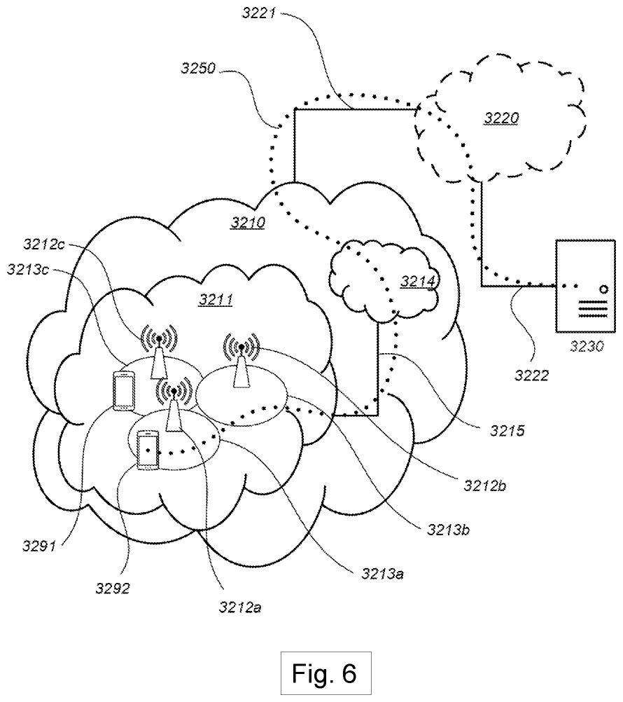

With reference to FIG. 6, in accordance with an embodiment, a communication system includes a telecommunication network 3210 such as the wireless communications network 100, e.g. an IoT network, or a WLAN, such as a 3GPP-type cellular network, which comprises an access network 3211, such as a radio access network, and a core network 3214. The access network 3211 comprises a plurality of base stations 3212a, 3212b, 3212c, such as the central node 130, distributed node 110, access nodes, AP STAs NBs, eNBs, gNBs or other types of wireless access points, each defining a corresponding coverage area 3213a, 3213b, 3213c. Each base station 3212a, 3212b, 3212c is connectable to the core network 3214 over a wired or wireless connection 3215. A first user equipment (UE) e.g. the UE 120 such as a Non-AP STA 3291 located in coverage area 3213c is configured to wirelessly connect to, or be paged by, the corresponding base station 3212c. A second UE 3292 such as a Non-AP STA in coverage area 3213a is wirelessly connectable to the corresponding base station 3212a. While a plurality of UEs 3291, 3292 are illustrated in this example, the disclosed embodiments are equally applicable to a situation where a sole UE is in the coverage area or where a sole UE is connecting to the corresponding base station 3212.

The telecommunication network 3210 is itself connected to a host computer 3230, which may be embodied in the hardware and/or software of a standalone server, a cloud-implemented server, e.g. cloud 140, a distributed server or as processing resources in a server farm. The host computer 3230 may be under the ownership or control of a service provider, or may be operated by the service provider or on behalf of the service provider. The connections 3221, 3222 between the telecommunication network 3210 and the host computer 3230 may extend directly from the core network 3214 to the host computer 3230 or may go via an optional intermediate network 3220. The intermediate network 3220 may be one of, or a combination of more than one of, a public, private or hosted network; the intermediate network 3220, if any, may be a backbone network or the Internet; in particular, the intermediate network 3220 may comprise two or more sub-networks (not shown).

The communication system of FIG. 6 as a whole enables connectivity between one of the connected UEs 3291, 3292 and the host computer 3230. The connectivity may be described as an over-the-top (OTT) connection 3250. The host computer 3230 and the connected UEs 3291, 3292 are configured to communicate data and/or signaling via the OTT connection 3250, using the access network 3211, the core network 3214, any intermediate network 3220 and possible further infrastructure (not shown) as intermediaries. The OTT connection 3250 may be transparent in the sense that the participating communication devices through which the OTT connection 3250 passes are unaware of routing of uplink and downlink communications. For example, a base station 3212 may not or need not be informed about the past routing of an incoming downlink communication with data originating from a host computer 3230 to be forwarded (e.g., handed over) to a connected UE 3291. Similarly, the base station 3212 need not be aware of the future routing of an outgoing uplink communication originating from the UE 3291 towards the host computer 3230.

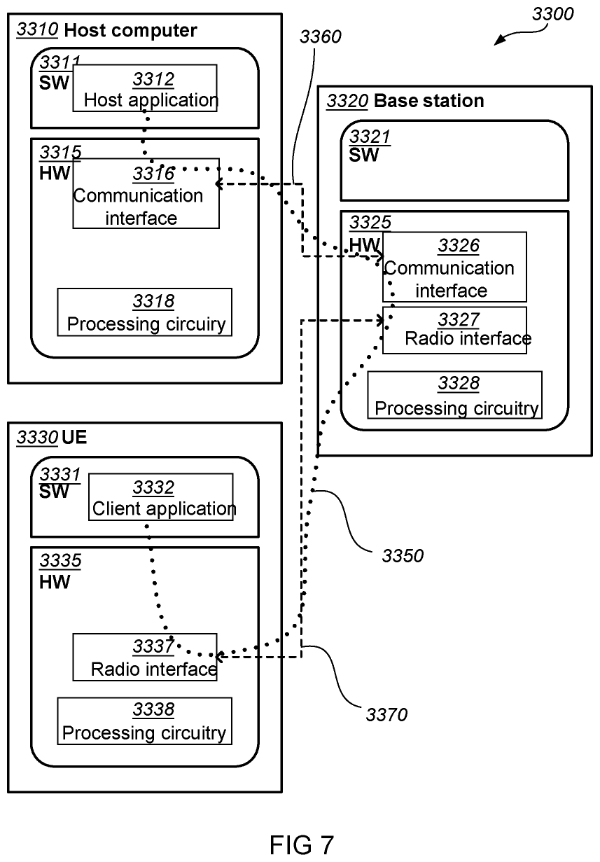

Example implementations, in accordance with an embodiment, of the UE, base station and host computer discussed in the preceding paragraphs will now be described with reference to FIG. 7. In a communication system 3300, a host computer 3310 comprises hardware 3315 including a communication interface 3316 configured to set up and maintain a wired or wireless connection with an interface of a different communication device of the communication system 3300. The host computer 3310 further comprises processing circuitry 3318, which may have storage and/or processing capabilities. In particular, the processing circuitry 3318 may comprise one or more programmable processors, application-specific integrated circuits, field programmable gate arrays or combinations of these (not shown) adapted to execute instructions. The host computer 3310 further comprises software 3311, which is stored in or accessible by the host computer 3310 and executable by the processing circuitry 3318. The software 3311 includes a host application 3312. The host application 3312 may be operable to provide a service to a remote user, such as a UE 3330 connecting via an OTT connection 3350 terminating at the UE 3330 and the host computer 3310. In providing the service to the remote user, the host application 3312 may provide user data which is transmitted using the OTT connection 3350.

The communication system 3300 further includes a base station 3320 provided in a telecommunication system and comprising hardware 3325 enabling it to communicate with the host computer 3310 and with the UE 3330. The hardware 3325 may include a communication interface 3326 for setting up and maintaining a wired or wireless connection with an interface of a different communication device of the communication system 3300, as well as a radio interface 3327 for setting up and maintaining at least a wireless connection 3370 with a UE 3330 located in a coverage area (not shown) served by the base station 3320. The communication interface 3326 may be configured to facilitate a connection 3360 to the host computer 3310. The connection 3360 may be direct or it may pass through a core network (not shown in FIG. 7) of the telecommunication system and/or through one or more intermediate networks outside the telecommunication system. In the embodiment shown, the hardware 3325 of the base station 3320 further includes processing circuitry 3328, which may comprise one or more programmable processors, application-specific integrated circuits, field programmable gate arrays or combinations of these (not shown) adapted to execute instructions. The base station 3320 further has software 3321 stored internally or accessible via an external connection.

The communication system 3300 further includes the UE 3330 already referred to. Its hardware 3335 may include a radio interface 3337 configured to set up and maintain a wireless connection 3370 with a base station serving a coverage area in which the UE 3330 is currently located. The hardware 3335 of the UE 3330 further includes processing circuitry 3338, which may comprise one or more programmable processors, application-specific integrated circuits, field programmable gate arrays or combinations of these (not shown) adapted to execute instructions. The UE 3330 further comprises software 3331, which is stored in or accessible by the UE 3330 and executable by the processing circuitry 3338. The software 3331 includes a client application 3332. The client application 3332 may be operable to provide a service to a human or non-human user via the UE 3330, with the support of the host computer 3310. In the host computer 3310, an executing host application 3312 may communicate with the executing client application 3332 via the OTT connection 3350 terminating at the UE 3330 and the host computer 3310. In providing the service to the user, the client application 3332 may receive request data from the host application 3312 and provide user data in response to the request data. The OTT connection 3350 may transfer both the request data and the user data. The client application 3332 may interact with the user to generate the user data that it provides.

It is noted that the host computer 3310, base station 3320 and UE 3330 illustrated in FIG. 7 may be identical to the host computer 3230, one of the base stations 3212a, 3212b, 3212c and one of the UEs 3291, 3292 of FIG. 6, respectively. This is to say, the inner workings of these entities may be as shown in FIG. 7 and independently, the surrounding network topology may be that of FIG. 6.

In FIG. 7, the OTT connection 3350 has been drawn abstractly to illustrate the communication between the host computer 3310 and the use equipment 3330 via the base station 3320, without explicit reference to any intermediary devices and the precise routing of messages via these devices. Network infrastructure may determine the routing, which it may be configured to hide from the UE 3330 or from the service provider operating the host computer 3310, or both. While the OTT connection 3350 is active, the network infrastructure may further take decisions by which it dynamically changes the routing (e.g., on the basis of load balancing consideration or reconfiguration of the network).

The wireless connection 3370 between the UE 3330 and the base station 3320 is in accordance with the teachings of the embodiments described throughout this disclosure. One or more of the various embodiments improve the performance of OTT services provided to the UE 3330 using the OTT connection 3350, in which the wireless connection 3370 forms the last segment. More precisely, the teachings of these embodiments may improve the applicable RAN effect: data rate, latency, power consumption, and thereby provide benefits such as corresponding effect on the OTT service: e.g. reduced user waiting time, relaxed restriction on file size, better responsiveness, extended battery lifetime.

A measurement procedure may be provided for the purpose of monitoring data rate, latency and other factors on which the one or more embodiments improve. There may further be an optional network functionality for reconfiguring the OTT connection 3350 between the host computer 3310 and UE 3330, in response to variations in the measurement results. The measurement procedure and/or the network functionality for reconfiguring the OTT connection 3350 may be implemented in the software 3311 of the host computer 3310 or in the software 3331 of the UE 3330, or both. In embodiments, sensors (not shown) may be deployed in or in association with communication devices through which the OTT connection 3350 passes; the sensors may participate in the measurement procedure by supplying values of the monitored quantities exemplified above, or supplying values of other physical quantities from which software 3311, 3331 may compute or estimate the monitored quantities. The reconfiguring of the OTT connection 3350 may include message format, retransmission settings, preferred routing etc.; the reconfiguring need not affect the base station 3320, and it may be unknown or imperceptible to the base station 3320. Such procedures and functionalities may be known and practiced in the art. In certain embodiments, measurements may involve proprietary UE signaling facilitating the host computer's 3310 measurements of throughput, propagation times, latency and the like. The measurements may be implemented in that the software 3311, 3331 causes messages to be transmitted, in particular empty or ‘dummy’ messages, using the OTT connection 3350 while it monitors propagation times, errors etc.

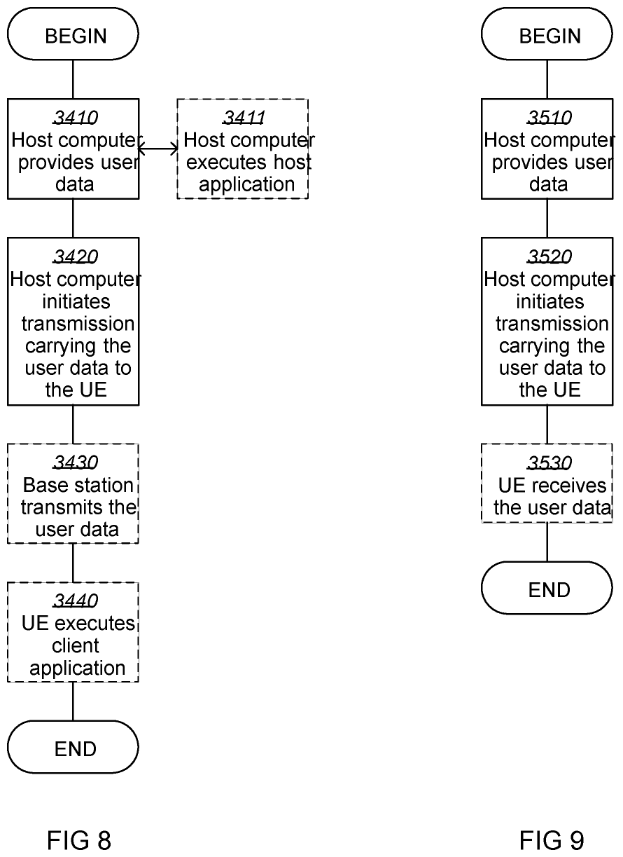

FIG. 8 is a flowchart illustrating a method implemented in a communication system, in accordance with one embodiment. The communication system includes a host computer, a base station such as the central node 130, and a UE such as the UE 120, which may be those described with reference to FIG. 6 and FIG. 7. For simplicity of the present disclosure, only drawing references to FIG. 8 will be included in this section. In a first action 3410 of the method, the host computer provides user data. In an optional subaction 3411 of the first action 3410, the host computer provides the user data by executing a host application. In a second action 3420, the host computer initiates a transmission carrying the user data to the UE. In an optional third action 3430, the base station transmits to the UE the user data which was carried in the transmission that the host computer initiated, in accordance with the teachings of the embodiments described throughout this disclosure. In an optional fourth action 3440, the UE executes a client application associated with the host application executed by the host computer.

FIG. 9 is a flowchart illustrating a method implemented in a communication system, in accordance with one embodiment. The communication system includes a host computer, a base station such as an AP STA, and a UE such as a Non-AP STA which may be those described with reference to FIG. 6 and FIG. 7. For simplicity of the present disclosure, only drawing references to FIG. 9 will be included in this section. In a first action 3510 of the method, the host computer provides user data. In an optional subaction (not shown) the host computer provides the user data by executing a host application. In a second action 3520, the host computer initiates a transmission carrying the user data to the UE. The transmission may pass via the base station, in accordance with the teachings of the embodiments described throughout this disclosure. In an optional third action 3530, the UE receives the user data carried in the transmission.

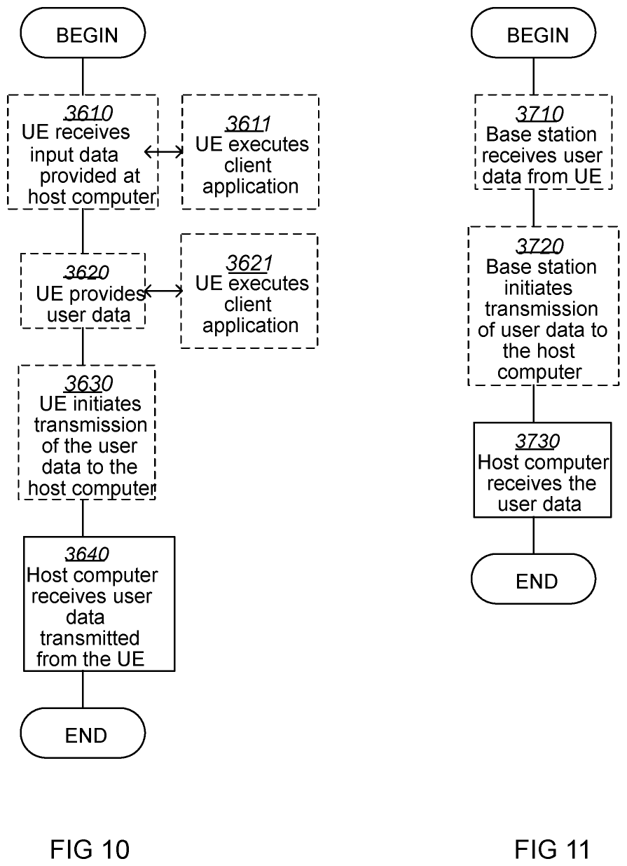

FIG. 10 is a flowchart illustrating a method implemented in a communication system, in accordance with one embodiment. The communication system includes a host computer, a base station such as an AP STA, and a UE such as a Non-AP STA which may be those described with reference to FIG. 6 and FIG. 7. For simplicity of the present disclosure, only drawing references to FIG. 10 will be included in this section. In an optional first action 3610 of the method, the UE receives input data provided by the host computer. Additionally, or alternatively, in an optional second action 3620, the UE provides user data. In an optional subaction 3621 of the second action 3620, the UE provides the user data by executing a client application. In a further optional subaction 3611 of the first action 3610, the UE executes a client application which provides the user data in reaction to the received input data provided by the host computer. In providing the user data, the executed client application may further consider user input received from the user. Regardless of the specific manner in which the user data was provided, the UE initiates, in an optional third subaction 3630, transmission of the user data to the host computer. In a fourth action 3640 of the method, the host computer receives the user data transmitted from the UE, in accordance with the teachings of the embodiments described throughout this disclosure.

FIG. 11 is a flowchart illustrating a method implemented in a communication system, in accordance with one embodiment. The communication system includes a host computer, a base station such as an AP STA, and a UE such as a Non-AP STA which may be those described with reference to FIG. 6 and FIG. 7. For simplicity of the present disclosure, only drawing references to FIG. 11 will be included in this section. In an optional first action 3710 of the method, in accordance with the teachings of the embodiments described throughout this disclosure, the base station receives user data from the UE. In an optional second action 3720, the base station initiates transmission of the received user data to the host computer. In a third action 3730, the host computer receives the user data carried in the transmission initiated by the base station.

1. A method performed by a central node for controlling an exploration strategy associated to Reinforcement Learning, RL, in one or more RL modules in a distributed node in a Radio Access Network, RAN, the method comprising:
evaluating a cost of actions performed for explorations in the one or more RL modules, and a performance of the one or more RL modules,
based on the evaluation, determining one or more exploration parameters associated to the exploration strategy, and,
controlling the exploration strategy by configuring the one or more RL modules with the determined one or more exploration parameters to update its exploration strategy, enforcing the respective one or more RL modules to act according to the updated exploration strategy to produce data samples for the one or more RL modules in the distributed node.

2. The method according to claim 1, further being for controlling a training strategy associated to the RL in the one or more RL modules in the distributed node, the method further comprises:
based on the evaluation, determining one or more training parameters, which one or more training parameters are associated to the training strategy,
configuring the one or more RL modules with the determined one or more training parameters to update its training strategy,
enforcing the respective one or more RL modules in the distributed node to act according to the updated training strategy to use the produced data samples to update an RL policy of the RL module.

3. The method according to claim 1, wherein the one or more exploration parameters are determined for a specific cell or group of cells controlled by the distributed node.

4. The method according to claim 1, wherein the one or more exploration parameters are determined further based on any one or more out of:
a performance of the RAN and
service requirements associated to services and applications provided by the distributed node,
importance of services provided by the distributed node.

5. The method according to claim 1, wherein the one or more exploration parameters comprises any one or more out of:
an index indicating a type of the exploration strategy, and
a value of the respective one or more exploration parameters.

6. The method according to claim 1, wherein the one or more training parameters are determined further based on any one or more out of:
importance of services provided by the distributed node,
requirements of services provided by the distributed node,
a search policy at the central node,
observed performance of the distributed node for a variety of Key Performance Indicators, KPIs.

7. The method according to claim 1, wherein the one or more training parameters comprises any one or more out of:
a discount factor for calculating the value of an action,
a type of gradient and the corresponding one or more training parameters, and
an index indicating a type of learning scheme.

8. The method according to claim 1, wherein any one or more out of:
configuring one or more RL modules with the determined one or more exploration parameters is performed by sending the one or more exploration parameters in a first control message, and
configuring one or more RL modules with the one or more training parameters, is performed by sending the one or more training parameters in a second control message.

9. A computer program comprising instructions, which when executed by a processor, causes the processor to perform actions according to claim 1.

10. A carrier comprising the computer program of claim 9, wherein the carrier is one of an electronic signal, an optical signal, an electromagnetic signal, a magnetic signal, an electric signal, a radio signal, a microwave signal, or a computer-readable storage medium.

11. A central node configured to control an exploration strategy associated to Reinforcement Learning, RL, in one or more RL modules in a distributed node in a Radio Access Network, RAN, wherein the central node is further configured to:
evaluate a cost of actions performed for explorations in the one or more RL modules, and a performance of the one or more RL modules,
based on the evaluation, determine one or more exploration parameters associated to the exploration strategy, and,
control the exploration strategy by configuring the one or more RL modules with the determined one or more exploration parameters to update its exploration strategy, to enforce the respective one or more RL modules to act according to the updated exploration strategy to produce data samples for the one or more RL modules in the distributed node.

12. The central node according to claim 11, further being configured to control a training strategy associated to the RL in the one or more RL modules in the distributed node, wherein the central node is further configured to:
based on the evaluation, determine one or more training parameters, which one or more training parameters are adapted to be associated to the training strategy,
configure the one or more RL modules with the determined one or more training parameters, to update its training strategy,
enforce the respective one or more RL modules in the distributed node to act according to the updated training strategy to use the produced data samples to update an RL policy of the RL module.

13. The central node according to claim 11, wherein the one or more exploration parameters are adapted to be determined for a specific cell or group of cells controlled by the distributed node.

14. The central node according to claim 11, wherein central node is further configured to determine the one or more exploration parameters based on any one or more out of:
a performance of the RAN and
service requirements associated to services and applications arranged to be provided by the distributed node,
importance of services arranged to be provided by the distributed node.

15. The central node according to claim 11, wherein the one or more exploration parameters are adapted to comprise any one or more out of:
an index adapted to indicate a type of the exploration strategy, and
a value of the respective one or more exploration parameters.

16. The central node according to claim 11, further being configured to determine the one or more training parameters based on any one or more out of:
importance of services arranged to be provided by the distributed node,
requirements of services arranged to be provided by the distributed node,
a search policy at the central node,
observed performance of the distributed node arranged for a variety of Key Performance Indicators, KPIs.

17. The central node according to claim 11, wherein the one or more training parameters are adapted to comprise any one or more out of:
a discount factor arranged for calculating the value of an action,
a type of gradient and the corresponding one or more training parameters, and
an index adapted to indicate a type of learning scheme.

18. The central node according to claim 11, wherein the central node is further configured to any one or more out of:
configure one or more RL modules with the determined one or more exploration parameters arranged to be performed by sending the one or more exploration parameters in a first control message, and
configure one or more RL modules with the one or more training parameters, arranged to be performed by sending the one or more training parameters in a second control message.
